(19) United States
(12) Patent Application Publication
(10) Pub. No.: US 2012/0134114 A1
(43) Pub. Date: May 31, 2012

(54) Thermal management of environmentally-sealed electronics enclosure

(76) Inventors: Nick Kamenszky, Saint Petersburg, FL (US); Art Ackerman, Valrico, FL (US); Jeff West, Brandon, FL (US); Chris Grassmuck, Peachtree City, GA (US); Michael J. Myers, Lutz, FL (US)

(21) Appl. No.: 13/137,131

(22) Filed: Jul. 22, 2011

Related U.S. Application Data
(60) Provisional application No. 61/344,436, filed on Jul. 22, 2010.

(51) Int. Cl. H05K 7/20

(52) U.S. Cl. 361/697

(57) ABSTRACT

Heat generated by operating electronic components within an environmentally-sealed enclosure is removed, without direct transmission of a viscous medium through the enclosure. An internal heat sink and external heat sink each span a given wall. The internal heat sink section is baffled and channeled with one place for air to enter, and one to exit. A fan forces air over heat sink extremities of the internal heat sink section. A circulating air column entrapped within the enclosure is drawn into the entrance of the internal heat sink, and forced through the entire length of the internal heat sink, providing for a thermal conduit for a heated entrapped air column to transfer its heat into the internal heat sink. The external heat sink is exposed to the ambient environment, with airflow managed over the external heat sink preferably with a structural surround that provides for channeling of airflow.

This application claims priority from U.S. Provisional No. 61/344,436 entitled “Thermal Management of Environmentally-Sealed Electronics Enclosure”, filed Jul. 22, 2010, the entirety of which is explicitly incorporated herein.

### BACKGROUND OF THE INVENTION

1. Field of the Invention

This invention relates to electronics, but more specifically to environmentally-sealed communications electronics.

2. Background of the Related Art

Existing cooling techniques within an environmentally-sealed enclosure implement active forced air cooling; passive convective cooling; coolant/heat exchanger schemes; and/or a heat pipe, but such techniques add significant weight to the device.

There is a need for a better apparatus and technique for cooling electronics enclosed within a portable, environmentally-sealed enclosure.

### SUMMARY OF THE INVENTION

An environmentally-sealed electronics enclosure comprises an environmentally-sealed enclosed volume including operable electronics. An internal heat sink section is sealed within the environmentally-sealed enclosed volume. The internal heat sink section includes a cavity forming an air column across internal heat sink extremities thereof, the cavity having an entrance and an exit. An internal heat sink fan is in communication with the entrance or exit of the cavity. An external heat sink section is in thermal communication with the internal heat sink section, and an external heat sink fan passes ambient air over external heat sink extremities thereof. In this way, the enclosed volume is cooled without direct transmission of a viscous medium through the environmentally-sealed enclosure.

In accordance with other aspects of the invention, a method of transferring heat from inside to outside an environmentally-sealed enclosure comprises sealing a heat sink through a wall of the environmentally-sealed enclosure, the heat sink having an internal heat sink section and an external heat sink section. A cavity is formed over internal heat sink extremities of the internal heat sink section, the internal cavity having an air entrance and an air exit. Air is blown through the internal cavity from the air entrance to the air exit. Ambient air is blown over external heat sink extremities of the external heat sink section.

### BRIEF DESCRIPTION OF THE DRAWINGS

Features and advantages of the present invention will become apparent to those skilled in the art from the following description with reference to the drawings, in which:

FIGS. 1A to 1C shows an exemplary environmentally-sealed enclosure including thermal management, in accordance with the principles of the present invention.

FIGS. 2A to 2C show details of an exemplary embodiment of an environmentally-sealed enclosure including thermal management, in accordance with the principles of the present invention.

FIG. 3 shows air column flow within the exemplary embodiment of an environmentally-sealed enclosure including thermal management, in accordance with the principles of the present invention.

### DETAILED DESCRIPTION OF ILLUSTRATIVE EMBODIMENTS

The present invention provides successful and efficient extraction and removal of excessive heat that is generated by operating electronic components within an environmentally-sealed enclosure, thus maintaining a sufficiently cool internal environment to allow housed electronic devices to operate within their respective acceptable operational temperature limits. The invention accomplishes efficient extraction and removal of excessive heat without direct transmission of a viscous medium (air, coolant, etc.) through the environmentally-sealed enclosure, thereby allowing for the operation of the electronics enclosure in harsh environments including dust, sand, precipitation, fog, corrosive salt air, etc.

A thermal management system is disclosed whereby a combination of conductive and convective heat transfer schemas are employed to eliminate and discard excessive heat from within an environmentally-sealed electronics enclosure to its ambient surroundings.

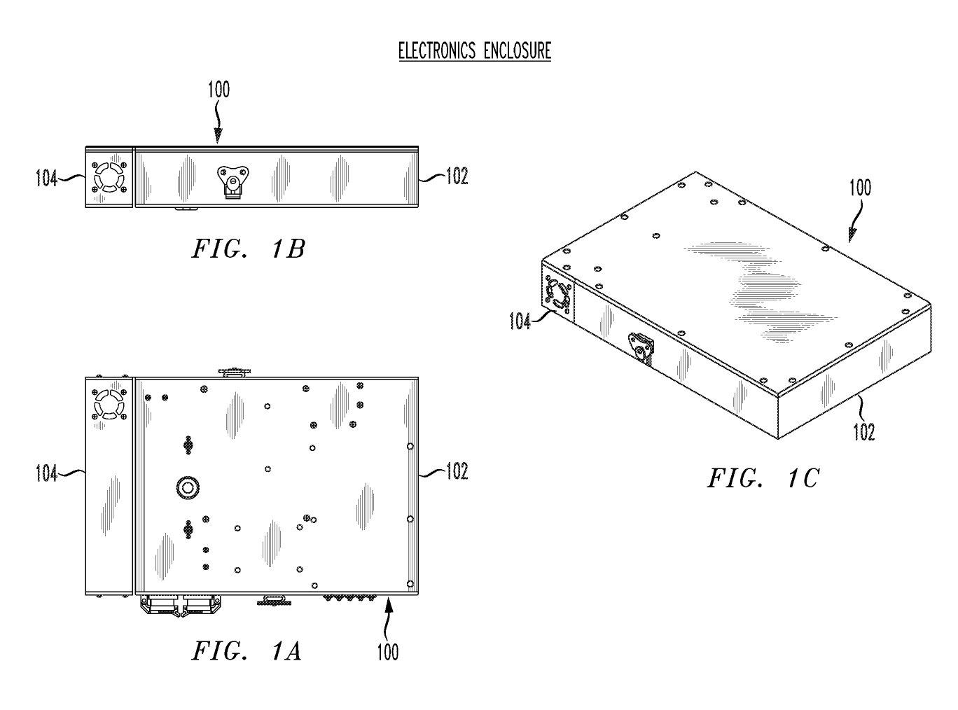

FIGS. 1A to 1C shows an exemplary environmentally-sealed enclosure including thermal management, in accordance with the principles of the present invention.

In particular, as shown in FIGS. 1A to 1C, an environmentally-sealed enclosure 100 includes a sealed electronics compartment 102, and an exposed cooling compartment 104.

The portable environmentally-sealable enclosure is created from a combination of materials including fabricated sheet metal, composites, plastics, etc. within which are contained numerous and various electronic components and their associated supporting hardware, wiring and peripherals. This enclosure when closed up is completely sealed from its external environment using any number and style of appropriate seals, sealant, and gaskets to isolate the internal volume from the surrounding environment and prevent any passage of fluids (air, humidity, precipitation) and contaminants from the surrounding ambient environment to the enclosed volume and vice versa.

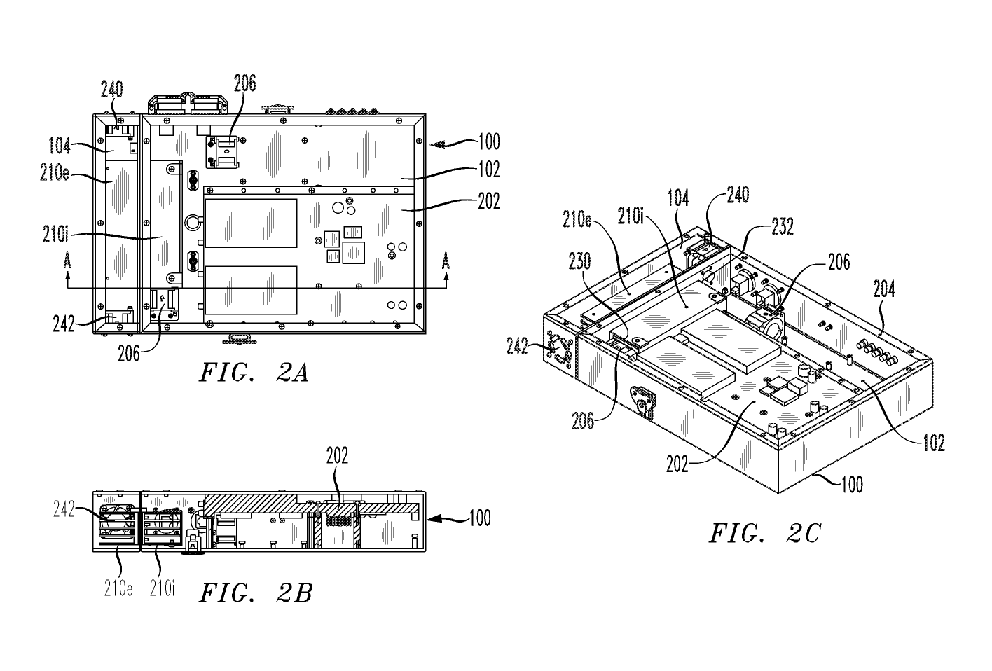

FIGS. 2A to 2C show details of an exemplary embodiment of an environmentally-sealed enclosure including thermal management (with a sealed lid removed for clarity), in accordance with the principles of the present invention.

In particular, as shown in FIGS. 2A to 2C, within the sealed electronics compartment 102 of the environmentally-sealed enclosure 100, are electronics 202.

Enclosed within the internal volume of the environmentally-sealed enclosure 100 there is one or more circulating fan or blower, referred to as an internal heat sink feed fan 206, with baffles and ducts strategically placed to create a continuous circulating flow of the entrapped air across and/or through the housed electronics devices. Depending upon the application, an additional circulating fan 208 may be included within the environmentally-sealed enclosure.

Heat is generated intrinsically by the operation of electronic components. This heat is removed from the electronic devices and convectively transferred to a circulating air column forced over the housed electronics devices by the baffles and ducts, thus lowering the temperature of the electronic devices while raising the temperature of the air after its passage.

A thermally conductive heat sink 210i, 210e is attached to one (or more) of the environmentally-sealed enclosure's walls or panels. The thermally conductive heat sink possesses a large amount of surface area to maximize its interaction with the air entrapped within the environmentally-sealed enclosure.

The thermally-conductive heat sink 210i, 210e can be of any suitable configuration including straight fin, pin matrix, folded fin, etc. The thermally-conductive heat sink 210i, 210e can be made of any suitable temperature-conductive material, e.g., aluminum, carbon, copper, etc.

The thermally-conductive heat sink 210i, 210e is sized and configured as appropriate to conduct an adequate magnitude of heat to sufficiently remove enough of the heat generated by the electronic components to permit desired operation of the electronics enclosed therein.

In the given embodiments, the thermally-conductive heat sink 210i, 210e is generally comprised of two sections—an internal heat sink section 210i located internal to the environmentally-sealed electronics enclosure, and an external heat sink section 210e located external to the environmentally-sealed electronics enclosure. In the given embodiments the internal heat sink section 210i and external heat sink section 210e each span a corresponding majority of a given wall of the environmentally-sealed enclosure 100.

The internal heat sink section 210i is baffled and channeled such that there exists preferably only one general place 230 for air to enter the internal heat sink section 210i, and preferably only one general place 232 for air to exit.

A fan or blower 206 is connected to at least one of the entrance 230 to the internal heat sink section 210i, and/or to the exit 232 of the internal heat sink section 210i. When the fan or blower 206 is blowing (presumably whenever the enclosed electronics is operating,) the circulating air column entrapped within the environmentally-sealed enclosure 100 is drawn into the entrance 230 of the internal heat sink section 210i, and then forced through the entire length of the internal heat sink section 210i, providing for a thermal conduit for the heated entrapped air column to transfer its heat into the internal heat sink section 210i.

The internal heat sink section 210i is physically and thermally mounted together to the external heat sink section 210e, through the one (or more) wall of the environmentally-sealed enclosure 100. In an alternative embodiment, the internal heat sink section 210i and the external heat sink section 210e may be fabricated into a single solidary element, in which case the environmentally-sealed enclosure 100 is environmentally-sealed against a central portion of the singular heat sink with appropriate sealant, gaskets, etc. against the wall of the environmentally-sealed enclosure 100. The environmentally-sealed enclosure 100 may itself be comprised of multiple panels, preferably sealed together with suitable gasket sealing surface(s) 204.

The external heat sink section 210e is exposed to the ambient environment. Airflow is managed over the external heat sink section 210e preferably with a structural surround that provides for channeling of airflow. The external heat sink section 210e is also fitted with one or more fan(s) and/or blower(s) 240, 242 to force external ambient air through the external heat sink section 210e, permitting heat on the external heat sink section 210e, transferred from the internal heat sink section 210i, to be transferred to the forced external air column and thus exhausted into the external ambient environment.

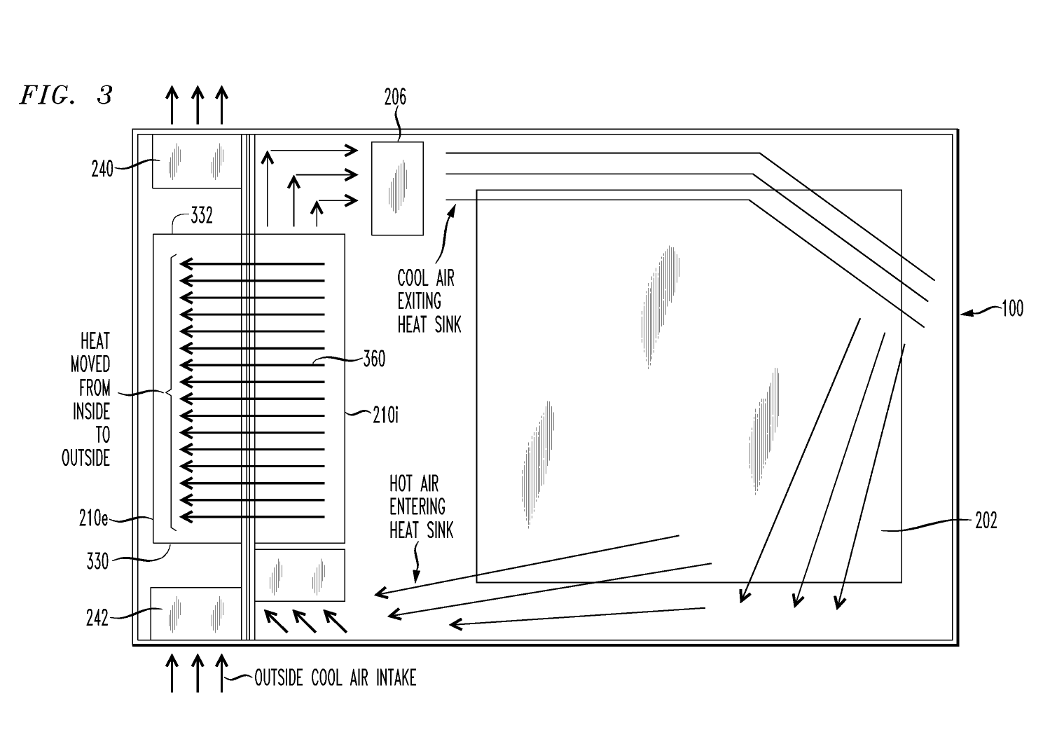

FIG. 3 shows air column flow within the exemplary embodiment of an environmentally-sealed enclosure including thermal management, in accordance with the principles of the present invention.

In particular, as shown in FIG. 3, an internal air column passes from the circulating fan 206, across an upper portion of the internal volume of the environmentally-sealed enclosure 100, around an end portion, over electronics 202 enclosed therein, back across a lower portion of the internal volume, and is drawn into the fan 206 at the entrance 230 to the internal heat sink section 210i. The air column is forced through the fins of the internal heat sink section 201i toward its exit 232, where it is drawn into the circulating fan 206. The internal air column continues in this manner.

The external heat sink section 210e has ambient air drawn into an entrance thereof 330 by way of a fan or blower 242, forced through the internal fins of the external heat sink section 210e, and pulled out of its exit 332 with an optional second fan or blower 240.

If the internal heat sink section 210i and external heat sink section 210e are separate elements, then it is preferable that they be thermally joined through the relevant wall of the environmentally-sealed enclosure 100. The thermal junction may preferably be facilitated with a suitable thermal epoxy, thermal resin, or thermal grease (also known as thermal gel, thermal compound, thermal paste, heat paste, heat sink paste, heat transfer compound, heat transfer paste, or heat sink compound). The arrows 360 depict head moved from inside to outside the environmentally-sealed enclosure 100.

While the invention has been described with reference to the exemplary embodiments thereof, those skilled in the art will be able to make various modifications to the described embodiments of the invention without departing from the true spirit and scope of the invention.

What is claimed is:

1. An environmentally-sealed electronics enclosure, comprising:
an environmentally-sealed enclosed volume including operable electronics;
an internal heat sink section sealed within said environmentally-sealed enclosed volume, said internal heat sink section including an internal cavity forming an air column across internal heat sink extremities thereof, said internal cavity having an entrance and an exit;
an internal heat sink fan in communication with one of said entrance or said exit of said internal cavity;
an external heat sink section in thermal communication with said internal heat sink section; and
an external heat sink fan to pass ambient air over external heat sink extremities thereof;
whereby said enclosed volume is cooled without direct transmission of a viscous medium through said environmentally-sealed enclosure.

2. The environmentally-sealed electronics enclosure according to claim 1, further comprising:
an exit fan at an exit of said internal cavity of said internal heat sink section.

3. The environmentally-sealed electronics enclosure according to claim 1, further comprising:
a circulation fan within said environmentally-sealed enclosed volume to facilitate passage of an air column over said operable electronics.

4. The environmentally-sealed electronics enclosure according to claim 1, wherein:
said external heat sink section includes a external cavity enclosing said external head sink extremities, said external heat sink fan being in communication with one of an entrance and an exit of said external cavity.

5. The environmentally-sealed electronics enclosure according to claim 1, further comprising:
a second external heat sink fan placed at an opposite opening of said external cavity of said external heat sink section to said external heat sink fan.

6. The environmentally-sealed electronics enclosure according to claim 1, wherein:
said thermal communication is physical contact between a significant area of said internal heat sink section and said external heat sink section.

7. The environmentally-sealed electronics enclosure according to claim 6, further comprising:
thermal grease to facilitate said physical contact between said internal heat sink section and said external heat sink section.

8. The environmentally-sealed electronics enclosure according to claim 6, further comprising:
thermal epoxy to facilitate said physical contact between said internal heat sink section and said external heat sink section.

9. The environmentally-sealed electronics enclosure according to claim 6, further comprising:
thermally conductive resin to facilitate said physical contact between said internal heat sink section and said external heat sink section.

10. A method of transferring heat from inside to outside an environmentally-sealed enclosure, comprising:
sealing a heat sink through a wall of said environmentally-sealed enclosure, said heat sink having an internal heat sink section and an external heat sink section;
forming an internal cavity over internal heat sink extremities of said internal heat sink section, said internal cavity having an air entrance and an air exit;
blowing air through said internal cavity from said air entrance to said air exit; and
blowing ambient air over external heat sink extremities of said external heat sink section.

11. The method of transferring heat from inside to outside an environmentally-sealed enclosure according to claim 10, further comprising:
forming an external cavity over said external heat sink extremities.
